(19) United States
(12) Patent Application Publication
(10) Pub. No.: US 2024/0309240 A1
(43) Pub. Date: Sep. 19, 2024

(54) POLISHING COMPOSITION, POLISHING METHOD, AND METHOD FOR PRODUCING SEMICONDUCTOR SUBSTRATE

(71) Applicant: FUJIMI INCORPORATED, Kiyosu-shi (JP)

(72) Inventors: Ryota MAE, Kiyosu-shi (JP); Akane KUMAYAMA, Kiyosu-shi (JP)

(73) Assignee: FUJIMI INCORPORATED, Kiyosu-shi (JP)

(21) Appl. No.: 18/602,204

(22) Filed: Mar. 12, 2024

(30) Foreign Application Priority Data
Mar. 14, 2023 (JP) 2023-039984

(51) Int. Cl. C09G 1/02

(52) U.S. Cl. CPC C09G 1/02

(57) ABSTRACT

The present invention provides a means capable of polishing a Low-k material and silicon nitride each at a high polishing removal rate and making a selection ratio of a polishing removal rate of the Low-k material to a polishing removal rate of the silicon nitride appropriate.

The present invention is a polishing composition containing abrasive grains and a quaternary phosphonium salt, in which a pH is less than 7.0, and a zeta potential of the abrasive grains in the polishing composition is −10 mV or less.

### TECHNICAL FIELD

The present invention relates to a polishing composition, a polishing method, and a method for producing a semiconductor substrate.

### BACKGROUND

In recent years, new microfabrication techniques have been developed along with high integration and high performance of LSI (Large Scale Integration). A chemical mechanical polishing (CMP) method is one of such techniques and is frequently employed in an LSI fabrication process, particularly, planarization of an interlayer insulating film in a multilayer interconnection forming process, formation of a metal plug, and formation of embedded wiring (damascene wiring).

As a material for the interlayer insulating film in the multilayer interconnection forming process, a low dielectric constant (Low-k) material is being adopted in order to suppress the inter-wiring capacitance. SiOC (carbon-containing silicon oxide doped with C in SiO₂) formed by a plasma CVD method is widely adopted as a low dielectric constant (Low-k) material.

As a technique for polishing SiOC, JP 2017-139349 A discloses a polishing composition containing: abrasive grains containing cerium; and a hydroxyalkyl cellulose and having a pH of 6.0 or more. According to JP 2017-139349 A, with such a configuration, a polishing removal rate of SiOC can be improved.

### SUMMARY

Recently, a substrate containing both a Low-k material such as SiOC and Si₃N₄ (silicon nitride) has been used. In such a substrate, there is an increasing demand to polish a Low-k material and silicon nitride at an appropriate selection ratio of polishing removal rates (for example, the polishing removal rate of the Low-k material/the polishing removal rate of Si₃N₄=1.0 or more and 2.0 or less) while polishing the Low-k material and the silicon nitride each at a high polishing removal rate. However, according to the polishing composition described in JP 2017-139349 A, there is a problem in that such a demand is not satisfied.

Therefore, an object of the present invention is to provide a means capable of polishing a Low-k material and silicon nitride each at a high polishing removal rate and making a selection ratio of a polishing removal rate of the Low-k material to a polishing removal rate of the silicon nitride appropriate.

The present inventors have conducted intensive studies to solve the above problems. As a result, the present inventors have found that the above problems may be solved by a polishing composition containing abrasive grains and a quaternary phosphonium salt, in which a pH is less than 7.0, and a zeta potential of the abrasive grains in the polishing composition is −10 mV or less, thereby completing the present invention.

### DETAILED DESCRIPTION

According to an embodiment of the present invention, there is provided a polishing composition containing abrasive grains and a quaternary phosphonium salt, in which a pH is less than 7.0, and a zeta potential of the abrasive grains in the polishing composition is −10 mV or less. According to such a polishing composition of the present invention, a Low-k material and silicon nitride can be polished each at a high polishing removal rate, and a selection ratio of a polishing removal rate of the Low-k material to a polishing removal rate of the silicon nitride can be made appropriate (for example, the polishing removal rate of the Low-k material/the polishing removal rate of Si₃N₄=1.0 or more and 2.0 or less).

The reason why the above effect is obtained by the polishing composition of the present invention is not clear in detail, but is considered to be the following mechanism. The mechanism is based on speculation, and the technical scope of the present invention is not limited by the mechanism.

The surface of the Low-k material is generally hydrophobic, but the quaternary phosphonium salt having an organic group is likely to adsorb to the Low-k material. Although the zeta potential of the surface of the Low-k material is close to 0 under acidic conditions, the zeta potential of the surface of the Low-k material on which the quaternary phosphonium salt is adsorbed turns positive (plus). As a result, the abrasive grains having a negative zeta potential of −10 mV or less are more likely to come into contact with the surface of the Low-k material having a positive zeta potential, and the contact frequency of the abrasive grains is increased, so that the polishing removal rate is increased. The quaternary phosphonium salt is hardly adsorbed on the surface of silicon nitride, and a high polishing removal rate can be maintained. As a result, the polishing removal rates of the Low-k material and silicon nitride are increased, and the selection ratio of the polishing removal rate of the Low-k material to the polishing removal rate of the silicon nitride can be set to an appropriate selection ratio (for example, the polishing removal rate of the Low-k material/the polishing removal rate of Si₃N₄=1.0 or more and 2.0 or less).

Hereinafter, embodiments of the present invention will be described in detail; however, the present invention is not limited only to the following embodiments, and various modifications can be made within the scope of claims. The embodiments described in the present specification may be other embodiments by being arbitrarily combined. In the present specification, unless otherwise specified, operations and measurements of physical properties and the like are performed under conditions of room temperature (20° C. or higher and 25° C. or lower)/relative humidity of 40% RH or more and 50% RH or less.

### Abrasive Grains

The polishing composition according to the present invention contains abrasive grains. The abrasive grains have an action of mechanically polishing an object to be polished, and improve the polishing removal rate of the object to be polished by the polishing composition.

In the polishing composition of the present invention, the abrasive grains have a zeta potential of −10 mV or less. Here, the “zeta (ζ) potential” is a potential difference generated at an interface between a solid and a liquid in contact with each other when the solid and the liquid perform relative movement. When the zeta potential of the abrasive grains exceeds −10 mV, the polishing removal rates of the Low-k material and silicon nitride decrease.

In the polishing composition of the present invention, the zeta potential of the abrasive grains is preferably −60 mV or more and −10 mV or less, more preferably −50 mV or more and −10 mV or less, further preferably −45 mV or more and −15 mV or less, and particularly preferably −40 mV or more and −15 mV or less. When the abrasive grains have a zeta potential in such a range, the polishing removal rate of the object to be polished can be further improved. Here, the zeta potential of the abrasive grains in the polishing composition is a value measured by the method described in Examples. The zeta potential of the abrasive grains can be adjusted by the amount of an anionic group (particularly, an organic acid group) that the abrasive grains described below have, the pH of the polishing composition, and the like.

The type of abrasive grains is not particularly limited, and examples thereof include metal oxides such as silica, alumina, zirconia, and titania. The abrasive grains can be used singly or in combination of two or more kinds thereof. As the abrasive grains, a commercially available product or a synthetic product may be used.

The type of abrasive grains is preferably silica and more preferably colloidal silica. Examples of the method for producing colloidal silica include a sodium silicate method and a sol-gel method, and any colloidal silica produced by any production method is suitably used as the abrasive grains of the present invention. However, from the viewpoint of reducing metal impurities, colloidal silica produced by a sol-gel method capable of producing colloidal silica with high purity is preferable.

The production of colloidal silica by the sol-gel method can be performed using a conventionally known method, and specifically, colloidal silica can be obtained by performing a hydrolysis/condensation reaction using a hydrolyzable silicon compound (for example, an alkoxysilane or a derivative thereof) as a raw material.

In some embodiments of the present invention, the colloidal silica contained in the polishing composition is preferably anion-modified colloidal silica and more preferably colloidal silica having an organic acid immobilized on the surface thereof. The colloidal silica having an organic acid immobilized on the surface thereof tends to have a larger absolute value of the zeta potential in the polishing composition than normal colloidal silica having no organic acid immobilized thereon. Therefore, the zeta potential of the colloidal silica in the polishing composition is easy to adjust to negative (for example, in a range of −40 mV or more and −15 mV or less).

Preferable examples of the colloidal silica having an organic acid immobilized on the surface thereof include colloidal silica in which an organic acid group such as a carboxylic acid group, a sulfonic acid group, a phosphonic acid group, or an aluminic acid group is immobilized on the surface thereof. Among them, from the viewpoint of easy production, colloidal silica having a sulfonic acid or a carboxylic acid immobilized on the surface thereof is preferable, and colloidal silica having a sulfonic acid immobilized on the surface thereof is more preferable.

The immobilization of the organic acid on the surface of the colloidal silica is not achieved by simply allowing the colloidal silica and the organic acid to coexist. For example, when a sulfonic acid, which is a kind of the organic acid, is immobilized on the colloidal silica, it is possible to perform the immobilization, for example, by the method described in “Sulfonic acid-functionalized silica through quantitative oxidation of thiol groups”, Chem. Commun. 246-247 (2003). Specifically, it is possible to obtain colloidal silica having sulfonic acid immobilized on the surface thereof (sulfonic acid-modified colloidal silica) by coupling a silane coupling agent having a thiol group such as 3-mercaptopropyl trimethoxysilane to colloidal silica and then oxidizing the thiol group with hydrogen peroxide.

Alternatively, when a carboxylic acid, which is a kind of the organic acid, is immobilized on the colloidal silica, it is possible to perform the immobilization, for example, by the method described in “Novel Silane Coupling Agents Containing a Photolabile 2-Nitrobenzyl Ester for Introduction of a Carboxy Group on the Surface of Silica Gel”, Chemistry Letters, 3, 228-229 (2000). Specifically, it is possible to obtain colloidal silica having carboxylic acid immobilized on the surface thereof (carboxylic acid-modified colloidal silica) by coupling a silane coupling agent containing a photoreactive 2-nitrobenzyl ester to colloidal silica and then irradiating with light.

The shape of the abrasive grains is not particularly limited, and may have a spherical shape or a non-spherical shape. Specific examples of the non-spherical shape include various shapes including a polygonal pole shape such as a triangle pole and a square pole, a cylindrical shape, a bale shape in which a central portion of a cylinder is bulged more than an end portion, a donut shape in which a central portion of a disk is penetrated, a plate shape, a so-called cocoon shape having a narrow part in a central portion, a so-called associated type spherical shape in which a plurality of particles are integrated, a so-called confetti shape having a plurality of protrusions on the surface thereof, a rugby ball shape, and the like, and the non-spherical shape is not particularly limited.

The size of the abrasive grains is not particularly limited. For example, the average primary particle diameter of the abrasive grains is preferably 5 nm or more, more preferably 8 nm or more, further preferably 10 nm or more, and particularly preferably 12 nm or more. As the average primary particle diameter of the abrasive grains increases, the polishing removal rate of the object to be polished by the polishing composition is improved. The average primary particle diameter of the abrasive grains is preferably 100 nm or less, more preferably 50 nm or less, further preferably 30 nm or less, and particularly preferably 20 nm or less. As the average primary particle diameter of the abrasive grains decreases, it is easier to obtain a surface with fewer defects by polishing using the polishing composition. That is, the average primary particle diameter of the abrasive grains is preferably 5 nm or more and 100 nm or less, more preferably 8 nm or more and 50 nm or less, further preferably 10 nm or more and 30 nm or less, and particularly preferably 12 nm or more and 20 nm or less. The average primary particle diameter of the abrasive grains can be calculated, for example, based on the specific surface area (SA) of the abrasive grains calculated from the BET method on the assumption that the shape of the abrasive grains is a true spherical shape. In the present specification, as the average primary particle diameter of the abrasive grains, a value measured by the method described in Examples is adopted.

The average secondary particle diameter of the abrasive grains is preferably 10 nm or more, more preferably 15 nm or more, further preferably 20 nm or more, and particularly preferably 25 nm or more. As the average secondary particle diameter of the abrasive grains increases, the resistance during polishing is decreased, and polishing can be stably performed. The average secondary particle diameter of the abrasive grains is preferably 400 nm or less, more preferably 300 nm or less, further preferably 200 nm or less, particularly preferably 100 nm or less, and most preferably 50 nm or less. As the average secondary particle diameter of the abrasive grains decreases, the surface area per unit mass of the abrasive grains increases, the frequency of contact with the object to be polished is improved, and the polishing removal rate is further improved. That is, the average secondary particle diameter of the abrasive grains is preferably 10 nm or more and 400 nm or less, more preferably 15 nm or more and 300 nm or less, further preferably 20 nm or more and 200 nm or less, particularly preferably 25 nm or more and 100 nm or less, and particularly preferably 25 nm or more and 50 nm or less. The average secondary particle diameter of the abrasive grains can be measured by, for example, a dynamic light scattering method represented by a laser diffraction scattering method.

The average association degree of the abrasive grains is preferably 5.0 or less, more preferably 4.0 or less, further preferably 3.0 or less, and particularly preferably 2.5 or less. As the average association degree of the abrasive grains decreases, defects can be further reduced. The average association degree of the abrasive grains is also preferably 1.0 or more, more preferably 1.5 or more, and further preferably 2.0 or more. The average association degree is obtained by dividing the value of the average secondary particle diameter of the abrasive grains by the value of the average primary particle diameter of the abrasive grains. As the average association degree of the abrasive grains increases, there is a favorable effect that the polishing removal rate of the object to be polished by the polishing composition is improved.

The upper limit of an aspect ratio of the abrasive grains in the polishing composition is not particularly limited, and is preferably less than 2.0, more preferably 1.8 or less, and further preferably 1.5 or less. Within such a range, defects on the surface of the object to be polished can be further reduced. The aspect ratio is an average of values obtained by taking the smallest rectangle circumscribing the image of an abrasive grain particle with a scanning electron microscope and dividing the length of a long side of the rectangle by the length of a short side of the same rectangle, and can be determined using general image analysis software. The lower limit of the aspect ratio of the abrasive grains in the polishing composition is not particularly limited, and is preferably 1.0 or more and more preferably 1.2 or more.

In the particle size distribution of the abrasive grains determined by a laser diffraction scattering method, the lower limit of a ratio D90/D10 of a particle diameter (D90) when the integrated particle mass from the fine particle side reaches 90% of the total particle mass and a particle diameter (D10) when the integrated particle mass from the fine particle side reaches 10% of the total particle mass is not particularly limited, and is preferably 1.1 or more, more preferably 1.4 or more, further preferably 1.7 or more, and most preferably 2.0 or more. In the particle size distribution of the abrasive grains in the polishing composition determined by a laser diffraction scattering method, the upper limit of the ratio D90/D10 of the particle diameter (D90) when the integrated particle mass from the fine particle side reaches 90% of the total particle mass and the particle diameter (D10) when the integrated particle mass from the fine particle side reaches 10% of the total particle mass is not particularly limited, and is preferably 3.0 or less and more preferably 2.5 or less. Within such a range, defects on the surface of the object to be polished can be further reduced.

The size (average primary particle diameter, average secondary particle diameter, aspect ratio, D90/D10, or the like) of the abrasive grains can be appropriately controlled by selection of the method for producing the abrasive grains, and the like.

The concentration (content) of the abrasive grains is not particularly limited, and is preferably 0.5% by mass or more, more preferably 0.8% by mass or more, further preferably 1% by mass or more, still more preferably more than 1% by mass, and particularly preferably 1.5% by mass or more, with respect to the total mass of the polishing composition. The upper limit of the concentration (content) of the abrasive grains is preferably 20% by mass or less, more preferably 15% by mass or less, further preferably 10% by mass or less, and particularly preferably 5% by mass or less, with respect to the total mass of the polishing composition. That is, the concentration (content) of the abrasive grains is preferably 0.5% by mass or more and 20% by mass or less, more preferably 0.8% by mass or more and 20% by mass or less, further preferably 1% by mass or more and 15% by mass or less, still more preferably more than 1% by mass and 10% by mass or less, and particularly preferably 1.5% by mass or more and 5% by mass or less, with respect to the total mass of the polishing composition. Within such a range, the polishing removal rate can be improved while suppressing the cost. When the polishing composition contains two or more kinds of abrasive grains, the concentration (content) of the abrasive grains means the total amount thereof.

### Quaternary Phosphonium Salt

The polishing composition according to the present invention contains a quaternary phosphonium salt. As described above, the quaternary phosphonium salt has an effect of turning the zeta potential of the surface of the Low-k material positive, and can improve the polishing removal rate of the Low-k material.

From the viewpoint of further improving the effect of the present invention, the quaternary phosphonium salt according to the present invention preferably has at least one of a substituted or unsubstituted aryl group bonded to a phosphorus atom and a substituted or unsubstituted alkyl group bonded to a phosphorus atom. Examples of the substituent which the aryl group and the alkyl group may have include a halogen atom, a hydroxy group, a carboxy group, a cyano group, a nitro group, an amino group, a monoalkylamino group, a dialkylamino group, a trialkylsilyl group, an aliphatic heterocyclic group, an aryl group, an alkyl group, and the like. The alkyl group bonded to a phosphorus atom is not substituted with an alkyl group.

The aryl group bonded to a phosphorus atom is not particularly limited, and examples thereof include aryl groups having 6 to 20 carbon atoms such as a phenyl group, a naphthyl group, an anthracenyl group, a tetracenyl group, a phenanthryl group, a chrysenyl group, a triphenylenyl group, and a biphenyl group.

The alkyl group bonded to a phosphorus atom is not particularly limited, and examples thereof include linear or branched alkyl groups having 1 to 20 carbon atoms such as a methyl group, an ethyl group, a n-propyl group, an isopropyl group, a n-butyl group, a tert-butyl group, a sec-butyl group, a n-pentyl group, an isopentyl group, a n-hexyl group, an isohexyl group, a n-octyl group, an isooctyl group, a n-nonyl group, an isononyl group, a n-decyl group, an isodecyl group, a n-dodecyl group, an isododecyl group, an undecyl group, a lauryl group, a myristyl group, a cetyl group, a stearyl group, a 2-ethylhexyl group, and a 4-butyloctyl group; and cyclic alkyl groups having 3 to 20 carbon atoms (cycloalkyl groups) such as a cyclopropyl group, a cyclobutyl group, a cyclopentyl group, a cyclohexyl group, and the like.

More specific examples of the quaternary phosphonium salt include tetraphenylphosphonium fluoride, tetrabutylphosphonium fluoride, methyltriphenylphosphonium fluoride, ethyltriphenylphosphonium fluoride, propyltriphenylphosphonium fluoride, benzyltriphenylphosphonium fluoride, dodecyltriphenylphosphonium fluoride, hexadecyltri(n-butyl) phosphonium fluoride, and tetradecyltriphenylphosphonium fluoride;

tetra-n-butylphosphonium hydroxide, tetraethylphosphonium hydroxide, tetraphenylphosphonium hydroxide, methyltriphenylphosphonium hydroxide, ethyltriphenylphosphonium hydroxide, propyltriphenylphosphonium hydroxide, butyltriphenylphosphonium hydroxide, and benzyltriphenylphosphonium hydroxide;

tetra-n-butylphosphonium acetate, ethyltriphenylphosphonium acetate, and tetramethylphosphonium acetate;

tetrakis(hydroxymethyl)phosphonium sulfate;

benzyltriphenylphosphonium chloride, (4-chlorobenzyl)triphenylphosphonium chloride, (2-chlorobenzyl)triphenylphosphonium chloride, triphenyl(2-chlorobenzyl)phosphonium chloride, (chloromethyl)triphenylphosphonium chloride, (2,4-dichlorobenzyl)triphenylphosphonium chloride, (1-naphthylmethyl)triphenylphosphonium chloride, tetra-n-butylphosphonium chloride, tetrakis(hydroxymethyl)phosphonium chloride, and tetraphenylphosphonium chloride;

amyltriphenylphosphonium bromide, benzyltriphenylphosphonium bromide, (bromomethyl)triphenylphosphonium bromide, 3-bromopropyltriphenylphosphonium bromide, butyltriphenylphosphonium bromide, cyclopropyltriphenylphosphonium bromide, ethyltriphenylphosphonium bromide, heptyltriphenylphosphonium bromide, hexyltriphenylphosphonium bromide, (2-hydroxybenzyl)triphenylphosphonium bromide, methyltriphenylphosphonium bromide, (4-nitrobenzyl)triphenylphosphonium bromide, tetraethylphosphonium bromide, tetra-n-octylphosphonium bromide, tetraphenylphosphonium bromide, tri(n-butyl)dodecylphosphonium bromide, tri(n-butyl)hexadecylphosphonium bromide, tri(n-butyl)n-octylphosphonium bromide, triphenylpropylphosphonium bromide, and triphenyl(tetradecyl)phosphonium bromide;

ethyltriphenylphosphonium iodide, isopropyltriphenylphosphonium iodide, methyltriphenylphosphonium iodide, tetraphenylphosphonium iodide, and tri(n-butyl)methylphosphonium iodide; and

di-tert-butylmethylphosphonium tetraphenylborate, μ-oxo-bis[tris(dimethylamino)phosphonium]bis(tetrafluoroborate), tetra-n-butylphosphonium benzotriazolate, tetraethylphosphoniumtetrafluoroborate, tetrakis(hydroxymethyl)phosphonium sulfate, tetraphenylphosphonium tetraphenylborate, tetraphenylphosphonium tetra-p-tolylborate, tributyl(2-methoxyethyl) phosphonium bis(trifluoromethanesulfonyl)imide, tri-tert-butylphosphoniumtetrafluoroborate, tri-tert-butylphosphonium tetraphenylborate, tricyclohexylphosphoniumtetrafluoroborate, acetonyltriphenylphosphonium chloride, allyltriphenylphosphonium chloride, trans-2-butene-1,4-bis(triphenylphosphonium chloride), (cyanomethyl)triphenylphosphonium chloride, (formylmethyl)triphenylphosphonium chloride, (methoxymethyl)triphenylphosphonium chloride, tributyl(cyanomethyl)phosphonium chloride, 2-(trimethylsilyl)ethoxymethyltriphenylphosphonium chloride, allyltriphenylphosphonium bromide, (4-carboxybutyl)triphenylphosphonium bromide, (3-carboxypropyl)triphenylphosphonium bromide, cinnamyltriphenylphosphonium bromide, (3,4-dimethoxybenzyl)triphenylphosphonium bromide, 2-dimethylaminoethyltriphenylphosphonium bromide, 2-(1,3-dioxolane-2-yl)ethyltriphenylphosphonium bromide, (1,3-dioxolane-2-yl)methyltriphenylphosphonium bromide, 4-ethoxybenzyltriphenylphosphonium bromide, ethoxycarbonylmethyl(triphenyl)phosphonium bromide, methoxycarbonylmethyl(triphenyl)phosphonium bromide, phenacyltriphenylphosphonium bromide, tributyl (1,3-dioxolane-2-ylmethyl)phosphonium bromide, (3-trimethylsilyl-2-propynyl)triphenylphosphonium bromide, triphenylpropargylphosphonium bromide, triphenylvinylphosphonium bromide, (N-methyl-N-phenylamino)triphenylphosphonium iodide, (2-trimethylsilylethyl)triphenylphosphonium iodide, and the like.

These quaternary phosphonium salts can be used singly or in combination of two or more kinds thereof. As the quaternary phosphonium salt, a commercially available product or a synthetic product may be used.

Among these quaternary phosphonium salts, a compound having a substituted or unsubstituted linear or branched alkyl group bonded to a phosphorus atom is preferable. A compound having a tetraalkylphosphonium cation in which all four organic groups bonded to a phosphorus atom are alkyl groups is more preferable. The alkyl group is further preferably linear. The maximum number of carbon atoms of the alkyl group that the tetraalkylphosphonium cation has is particularly preferably 2 or more and 10 or less. When the maximum number of carbon atoms of the alkyl group is in this range, adsorption of the quaternary phosphonium salt to the Low-k material is appropriate, and the effect of turning the zeta potential of the surface of the Low-k material to positive is efficiently exhibited, so that a desired effect is more exhibited.

When the maximum number of carbon atoms of the alkyl group that the tetraalkylphosphonium cation has is 1, adsorption to the Low-k material is less likely to occur, and the polishing removal rate of the Low-k material may be less likely to be improved.

When the maximum number of carbon atoms of the alkyl group that the tetraalkylphosphonium cation has exceeds 10, the quaternary phosphonium salt is easily adsorbed on the surface of silicon nitride and acts like a protective film of silicon nitride, and the polishing removal rate of silicon nitride may be reduced. There is a case where aggregation of the abrasive grains is caused.

From the above points, the quaternary phosphonium salt used in the present invention is further preferably tetra-n-butylphosphonium fluoride, tetra-n-butylphosphonium hydroxide, tetraethylphosphonium hydroxide, tetra-n-butylphosphonium acetate, tetra-n-butylphosphonium chloride, tetraethylphosphonium bromide, tetra-n-octylphosphonium bromide, tri(n-butyl)n-octylphosphonium bromide, tri (n-butyl)methylphosphonium iodide, tetra-n-butylphosphonium benzotriazolate, and tetraethylphosphonium tetrafluoroborate, and is still more preferably at least one selected from the group consisting of tetra-n-butylphosphonium hydroxide, tetraethylphosphonium bromide, and tetra-n-octylphosphonium bromide. The quaternary phosphonium salt is particularly preferably at least one of tetra-n-butylphosphonium hydroxide and tetraethylphosphonium bromide.

The lower limit of the concentration (content) of the quaternary phosphonium salt in the polishing composition is preferably 0.001% by mass (10 ppm by mass) or more, more preferably 0.005% by mass (50 ppm by mass) or more, and further preferably 0.01% by mass (100 ppm by mass) or more. The upper limit of the concentration (content) of the quaternary phosphonium salt in the polishing composition is preferably 1% by mass (10000 ppm by mass) or less, more preferably 0.5% by mass (5000 ppm by mass) or less, further preferably 0.3% by mass (3000 ppm by mass) or less, and particularly preferably 0.1% by mass (1000 ppm by mass) or less. That is, the concentration (content) of the quaternary phosphonium salt in the polishing composition is preferably 0.001% by mass (10 ppm by mass) or more and 1% by mass (10000 ppm by mass) or less, more preferably 0.005% by mass (50 ppm by mass) or more and 0.5% by mass (5000 ppm by mass) or less, further preferably 0.01% by mass (100 ppm by mass) or more and 0.3% by mass (3000 ppm by mass) or less, and particularly preferably 0.01% by mass (100 ppm by mass) or more and 0.1% by mass (1000 ppm by mass) or less.

When the polishing composition contains two or more kinds of quaternary phosphonium salts, the concentration (content) of the quaternary phosphonium salt means the total amount thereof.

### pH and pH Adjusting Agent

The pH of the polishing composition according to the present invention is less than 7.0. When the pH is 7.0 or more, the polishing removal rate of silicon nitride is particularly low, and the desired effect of the present invention cannot be obtained. The pH is preferably 1.0 or more, more preferably 1.5 or more, and further preferably 2.0 or more. The pH is preferably 6.0 or less, more preferably 5.0 or less, and further preferably 4.5 or less. That is, the pH of the polishing composition according to the present invention is preferably 1.0 or more and 6.0 or less, more preferably 1.5 or more and 5.0 or less, and further preferably 2.0 or more and 4.5 or less.

The polishing composition according to the present invention preferably contains a pH adjusting agent for adjusting the pH. The pH adjusting agent may be either an acid or a base, or may be either an inorganic compound or an organic compound. The pH adjusting agent can be used singly or as a mixture of two or more kinds thereof.

Specific examples of the acid that can be used as the pH adjusting agent include inorganic acids such as hydrochloric acid, sulfuric acid, nitric acid, hydrofluoric acid, boric acid, carbonic acid, hypophosphorous acid, phosphorous acid, and phosphoric acid; and organic acids such as formic acid, acetic acid, propionic acid, butyric acid, valeric acid, 2-methylbutyric acid, n-hexanoic acid, 3,3-dimethylbutyric acid, 2-ethylbutyric acid, 4-methylpentanoic acid, n-heptanoic acid, 2-methylhexanoic acid, n-octanoic acid, 2-ethylhexanoic acid, benzoic acid, glycolic acid, salicylic acid, glyceric acid, oxalic acid, malonic acid, succinic acid, glutaric acid, adipic acid, pimelic acid, maleic acid, phthalic acid, malic acid, tartaric acid, citric acid, lactic acid, diglycolic acid, 2-furancarboxylic acid, 2,5-furandicarboxylic acid, 3-furancarboxylic acid, 2-tetrahydrofurancarboxylic acid, methoxyacetic acid, methoxyphenylacetic acid, and phenoxyacetic acid.

Examples of the base that can be used as the pH adjusting agent include amines such as aliphatic amines and aromatic amines, organic bases such as quaternary ammonium hydroxide, hydroxides of alkali metals such as sodium hydroxide and potassium hydroxide, hydroxides of Group 2 elements, ammonia, and the like.

The addition amount of the pH adjusting agent is not particularly limited, and may be appropriately adjusted so that the polishing composition has a desired pH. The pH of the polishing composition can be measured by, for example, a pH meter, and specifically, can be measured by the method described in Examples.

### Dispersing Medium

The polishing composition according to the present invention preferably further contains a dispersing medium. Examples of the dispersing medium include water; alcohols such as methanol, ethanol, and ethylene glycol; ketones or the like such as acetone, mixtures thereof; and the like. Among them, water is preferable as the dispersing medium. That is, according to a more preferable embodiment of the present invention, the dispersing medium contains water. According to a further preferred embodiment of the present invention, the dispersing medium substantially consists of water. The term “substantially” as described above is intended to mean that a dispersing medium other than water can be contained as long as the objective effect of the present invention can be achieved, and more specifically, the dispersing medium is preferably composed of 90% by mass or more and 100% by mass or less of water and 0% by mass or more and 10% by mass or less of a dispersing medium other than water, and more preferably composed of 99% by mass or more and 100% by mass or less of water and 0% by mass or more and 1% by mass or less of a dispersing medium other than water. Most preferably, the dispersing medium is water.

From the viewpoint of preventing the action of the components contained in the polishing composition from being inhibited, water not containing impurities as much as possible is preferable as the dispersing medium, and specifically, pure water, ultrapure water, or distilled water from which impurity ions are removed with an ion exchange resin and then foreign substances are removed through a filter is more preferable.

### Electrical Conductivity of Polishing Composition

The electrical conductivity (EC) of the polishing composition according to the present invention is not particularly limited, and is preferably 1 mS/cm or more and more preferably 1.5 mS/cm or more. The electrical conductivity (EC) of the polishing composition according to the present invention is preferably 20 mS/cm or less and more preferably 15 mS/cm or less. That is, the electrical conductivity (EC) of the polishing composition according to the present invention is preferably 1 mS/cm or more and 20 mS/cm or less and more preferably 1.5 mS/cm or more and 15 mS/cm or less. When the electrical conductivity (EC) of the polishing composition is within such a range, the polishing removal rates of the Low-k material and silicon nitride can be maintained high, and repelling between the abrasive grains can be appropriately adjusted to ensure stability. The electrical conductivity of the polishing composition can be adjusted by the type, amount, and the like of the pH adjusting agent and the like, and the measurement of the electrical conductivity can be performed by the method described in Examples.

### Other Components

The polishing composition of the present invention may further contain known additives that can be used in the polishing composition, such as a water-soluble polymer, a complexing agent, a metal anticorrosive, an antiseptic agent, an antifungal agent, an oxidizing agent, a reducing agent, and a surfactant, as necessary. Among them, the polishing composition preferably contains an antifungal agent. The polishing composition according to the present invention is acidic. Therefore, the polishing composition more preferably contains an antifungal agent. That is, in an embodiment of the present invention, the polishing composition is substantially composed of abrasive grains, a quaternary phosphonium salt, a dispersing medium, and at least one of a pH adjusting agent and an antifungal agent. Here, the phrase “the polishing composition is substantially composed of abrasive grains, a quaternary phosphonium salt, a dispersing medium, and at least one of a pH adjusting agent and an antifungal agent” means that the total content of the abrasive grains, the quaternary phosphonium salt, the dispersing medium, and at least one of a pH adjusting agent and an antifungal agent exceeds 99% by mass with respect to the total mass of the polishing composition (upper limit: 100% by mass). Preferably, the polishing composition is composed of abrasive grains, a quaternary phosphonium salt, a dispersing medium, a pH adjusting agent, and an antifungal agent (the total content=100% by mass).

Hereinafter, an antifungal agent (antiseptic agent), which is the preferable other component, will be described. An oxidizing agent will also be described.

### Antifungal Agent

Examples of the antifungal agent (antiseptic agent) that can be added to the polishing composition according to the present invention include isothiazoline-based antiseptic agents such as 2-methyl-4-isothiazoline-3-one and 5-chloro-2-methyl-4-isothiazoline-3-one, paraoxybenzoic acid esters, phenoxyethanol, and the like. These antifungal agents (antiseptic agents) may be used singly or in combination of two or more kinds thereof.

### Oxidizing Agent

The polishing composition according to the present invention preferably does not substantially contain an oxidizing agent. When the oxidizing agent is contained in the polishing composition, the surface of the object to be polished is oxidized to generate an oxide film, and there is a concern that the polishing time becomes long. Specific examples of the oxidizing agent described herein include hydrogen peroxide (H₂O₂), sodium persulfate, ammonium persulfate, sodium dichloroisocyanurate, and the like. The fact that the polishing composition does not substantially contain an oxidizing agent means that the polishing composition does not at least intentionally contain an oxidizing agent. Therefore, a polishing composition inevitably containing a trace amount of an oxidizing agent derived from a raw material, a production method, or the like is included in the concept of the polishing composition that does not substantially contain an oxidizing agent. For example, the concentration (content) of the oxidizing agent in the polishing composition is preferably 0.01% by mass (100 ppm by mass) or less, more preferably less than 0.01% by mass (100 ppm by mass), and further preferably 0.005% by mass (50 ppm by mass) or less. The lower limit of the concentration (content) of the oxidizing agent is preferably 0% by mass or more and more preferably 0.0005% by mass (5 ppm by mass) or more.

### Form of Polishing Composition

The polishing composition according to the present invention is typically supplied to an object to be polished in the form of a polishing liquid containing the polishing composition, and is used for polishing the object to be polished. The polishing composition according to the present invention may be, for example, diluted (typically, diluted with water) and used as polishing liquid, or may be used as it is as a polishing liquid. That is, the concept of the polishing composition according to the present invention includes both a polishing composition (working slurry) which can be supplied to an object to be polished and used for polishing the object to be polished and a concentrated solution (a stock solution of a working slurry) which can be diluted and then used for polishing. The concentration rate of the concentrated solution can be, for example, about 2 times or more and 100 times or less on a volume basis, and usually about 3 times or more and 50 times or less is appropriate.

### Object to be Polished

The object to be polished according to the present invention is not particularly limited, and examples thereof include single crystal silicon, polycrystalline silicon (polysilicon), polycrystalline silicon doped with an n-type or p-type impurity, amorphous silicon, amorphous silicon doped with an n-type or p-type impurity, silicon oxide, silicon nitride, silicon carbonitride (SiCN), a metal, SiGe, a carbon-containing material, a low dielectric constant material (Low-k material), and the like.

Examples of the object to be polished containing silicon oxide include a TEOS type silicon oxide film (hereinafter, also simply referred to as “TEOS” or “TEOS film”) produced using tetraethyl orthosilicate as a precursor, an HDP (High Density Plasma) film, a USG (Undoped Silicate Glass) film, a PSG (Phosphorus Silicate Glass) film, a BPSG (Boron-Phospho Silicate Glass) film, an RTO (Rapid Thermal Oxidation) film, and the like.

Examples of the metal include tungsten, copper, aluminum, cobalt, hafnium, nickel, gold, silver, platinum, palladium, rhodium, ruthenium, iridium, osmium, and the like.

Examples of the carbon-containing material include materials other than the Low-k material such as amorphous carbon, spin-on carbon (SOC), diamond-like carbon (DLC), nanocrystalline diamond, and graphene.

The low dielectric constant material (Low-k material) is a material having a relative dielectric constant k lower than that of silicon oxide, preferably a material having a relative dielectric constant k of 3.0 or less. Specific examples thereof include silicon carbide (Sic), carbon-containing silicon oxide (SiOC), silicon oxide containing a methyl group, benzocyclobutene (BCB), fluorinated silicon oxide (SiOF), HSQ (hydrogen silsesquioxane), MSQ (methyl silsesquioxane), HMSQ (hydride-methyl silsesquioxane), a polyimide-based polymer, an arylene ether-based polymer, a cyclobutene-based polymer, perfluorocyclobutene (PFCB), and the like.

The object to be polished may be a commercially available product or may be manufactured by a known method.

Among them, an object to be polished containing a Low-k material and silicon nitride is preferable. Therefore, according to a preferred embodiment of the present invention, the polishing composition is used for polishing an object to be polished containing a Low-k material and silicon nitride. The Low-k material is preferably carbon-containing silicon oxide (SiOC).

### Method for Producing Polishing Composition

A method for producing a polishing composition according to the present embodiment is not particularly limited, and for example, the polishing composition can be obtained by stirring and mixing abrasive grains, a quaternary phosphonium salt, a dispersing medium, and other additives added as necessary. Details of each component are as described above.

The temperature at which respective components are mixed is not particularly limited, and is preferably 10° C. or higher and 40° C. or lower, and heating may be performed in order to increase the rate of dissolution. The mixing time is also not particularly limited as long as the mixture can be uniformly mixed.

### Polishing Method and Method for Producing Semiconductor Substrate

As described above, the polishing composition according to the present embodiment is particularly suitably used for polishing an object to be polished having a Low-k material and silicon nitride. Therefore, the present invention provides a polishing method for polishing an object to be polished containing a Low-k material and silicon nitride by the polishing composition according to the present embodiment. The present invention provides a method for producing a semiconductor substrate, including polishing a semiconductor substrate containing a Low-k material and silicon nitride by the polishing method described above.

As a polishing apparatus, it is possible to use a general polishing apparatus in which a holder for holding a substrate or the like having an object to be polished and a motor or the like capable of changing the number of revolutions are attached and which has a polishing table to which a polishing pad (polishing cloth) can be attached.

As the polishing pad, a general nonwoven fabric, polyurethane, a porous fluororesin, and the like can be used without particular limitation. The polishing pad is preferably grooved such polishing that a liquid is accumulated.

Regarding the polishing conditions, for example, the rotation speeds of the polishing table (platen) and the carrier (head) are preferably 10 rpm (0.17 s⁻¹) or more and 500 rpm (8.33 s⁻¹) or less. The pressure (polishing pressure) applied to the substrate having the object to be polished is preferably 0.5 psi (3.45 kPa) or more and 10 psi (68.9 kPa) or less.

The method of supplying the polishing composition to the polishing pad is not particularly limited, and for example, a method of continuously supplying the polishing composition by a pump or the like is adopted. This supply amount is not limited, but it is preferable that the surface of the polishing pad is covered with the polishing composition according to the present invention at all times.

The polishing composition according to the present embodiment may be a one-pack type or a multi-pack type including a two-pack type. The polishing composition according to the present invention may be prepared by diluting a stock solution of the polishing composition, for example, three times or more using a diluent such as water.

### Polishing Removal Rate

As described above, the polishing composition according to the present invention can polish the Low-k material and silicon nitride each at a high polishing removal rate.

In the present invention, the polishing removal rate of the Low-k material is preferably 300 Å/min or more, more preferably 400 Å/min or more, and further preferably 450 Å/min or more. The polishing removal rate of the silicon nitride is preferably 300 Å/min or more, more preferably 330 Å/min or more, and further preferably 360 Å/min or more.

### Selection Ratio

As described above, the polishing composition according to the present invention can control a ratio (selection ratio) of the polishing removal rate of the Low-k material to the polishing removal rate of the silicon nitride in an appropriate range.

In the present invention, the ratio of the polishing removal rate of the Low-k material to the polishing removal rate of the silicon nitride (Low-k material/silicon nitride) is preferably 1.0 or more and more preferably 1.1 or more. The ratio of the polishing removal rate of the Low-k material to the polishing removal rate of the silicon nitride (Low-k material/silicon nitride) is preferably 2.0 or less, more preferably 1.9 or less, and further preferably 1.7 or less. That is, the selection ratio may be 1.0 or more and 2.0 or less, 1.0 or more and 1.9 or less, or 1.0 or more and 1.7 or less. The selection ratio may be 1.1 or more and 2.0 or less, 1.1 or more and 1.9 or less, or 1.1 or more and 1.7 or less. When the selection ratio is out of the above range, the surface state of the finally obtained polished object to be polished may be deteriorated.

Although the embodiments of the present invention have been described in detail, this is illustrative and exemplary and not restrictive, and it is clear that the scope of the present invention should be interpreted by the appended claims.

The present invention includes the following aspects and embodiments.
1. A polishing composition containing: abrasive grains; and a quaternary phosphonium salt, in which a pH is less than 7.0, and a zeta potential of the abrasive grains in the polishing composition is −10 mV or less;
2. The polishing composition described in above item 1., in which the quaternary phosphonium salt has at least one of a substituted or unsubstituted aryl group bonded to a phosphorus atom and a substituted or unsubstituted alkyl group bonded to a phosphorus atom;
3. The polishing composition described in above item 1. or 2., in which the quaternary phosphonium salt has a substituted or unsubstituted alkyl group bonded to a phosphorus atom;
4. The polishing composition described in any one of above items 1. to 3., in which the quaternary phosphonium salt has a tetraalkylphosphonium cation, and a maximum number of carbon atoms of an alkyl group that the tetraalkylphosphonium cation has is 2 or more and 10 or less;
5. The polishing composition described in any one of above items 1. to 4., in which the quaternary phosphonium salt is at least one of tetra-n-butylphosphonium hydroxide and tetraethylphosphonium bromide;
6. The polishing composition described in any one of above items 1. to 5., in which the abrasive grains are anion-modified colloidal silica;
7. The polishing composition described in any one of above items 1. to 6., further containing a pH adjusting agent;
8. The polishing composition described in any one of above items 1. to 7., further containing a dispersing medium;
9. The polishing composition described in any one of above items 1. to 8., in which a concentration of an oxidizing agent in the polishing composition is less than 100 ppm by mass;
10. The polishing composition described in any one of above items 1. to 9., in which the zeta potential of the abrasive grains in the polishing composition is −40 mV or more and −15 mV or less;
11. The polishing composition described in any one of above items 1. to 10., which is used for polishing an object to be polished containing a Low-k material and silicon nitride;
12. The polishing composition described in above item 11., in which the Low-k material is SiOC;
13. The polishing composition described in any one of above item 11. or 12., in which a ratio of a polishing removal rate of the Low-k material to a polishing removal rate of the silicon nitride (Low-k material/silicon nitride) is 1.0 or more and 2.0 or less;
14. A polishing method comprising polishing an object to be polished containing a Low-k material and silicon nitride by using the polishing composition described in any one of above items 1. to 13.; and
15. A method for producing a semiconductor substrate, including polishing a semiconductor substrate containing a Low-k material and silicon nitride by the polishing method described in above item 14.

### Examples

The present invention will be described in more detail with the following Examples and Comparative Examples. However, the technical scope of the present invention is not limited only to the following Examples. Unless otherwise specified, “ %” and “part(s)” mean “% by mass” and “part(s) by mass”, respectively. In the following Examples, unless otherwise specified, the operation was performed under the conditions of room temperature (20° C. or higher and 25° C. or lower)/relative humidity of 40% RH or more and 50% RH or less. Each physical property was measured as follows.

### Average Secondary Particle Diameter of Abrasive Grains

The average secondary particle diameter of the abrasive grains was measured as a volume average particle diameter (volume-based arithmetic average diameter; Mv) by a dynamic light scattering particle size and particle size distribution apparatus UPA-UT151 (manufactured by NIKKISO CO., LTD.).

### Zeta Potential of Abrasive Grains

The zeta potential of the abrasive grains in the polishing composition was measured using a zeta potential measuring apparatus (instrument name “ELS-Z2”) manufactured by Otsuka Electronics Co., Ltd.

### pH of Polishing Composition

The pH of the polishing composition was measured by a pH meter (Model No.: LAQUA manufactured by HORIBA, Ltd.).

### Electrical Conductivity of Polishing Composition

The electrical conductivity (EC) of the polishing composition was measured by a tabletop-type electrical conductivity meter (Model No.: DS-71 LAQUA (registered trademark) manufactured by HORIBA, Ltd.).

### Sulfonic Acid-Immobilized Colloidal Silica

### Production Example 1

Sulfonic acid-modified silica particles (surface-modified silica 1) as abrasive grains were obtained according to the following procedure.

### Step of Preparing Raw Material Colloidal Silica Dispersion (Unmodified Silica Particles))

In a flask, 4080 g of methanol, 610 g of water, and 168 g of a 29% by mass aqueous ammonia solution were mixed, the liquid temperature was maintained at 20° C., and a mixed solution of 135 g of methanol and 508 g of tetramethoxysilane (TMOS) was added dropwise thereto for a dropwise addition time of 25 minutes. Thereafter, the resultant mixture was subjected to heat concentrated water replacement under a condition of pH 7 or more, and 1000 g of 19.5% by mass silica sol was obtained (average secondary particle diameter: 34 nm).

### Surface Modification Step

Subsequently, to 1000 g (195 g in terms of silica solid content) of the silica sol obtained above, 1.2 g of 3-mercaptopropyl trimethoxysilane (MPS, silane coupling agent, product name: KBM-803, manufactured by Shin-Etsu Chemical Co., Ltd.) (silane coupling agent concentration with respect to the total mass of silica solid content: 0.6% by mass) separately mixed with 4.8 g of methanol was added dropwise at a flow rate of 1 mL/min. Thereafter, heating was performed, and pure water replacement was performed for 3 hours after boiling.

Next, for cooling, the reaction solution was left to stand still overnight, 0.0343 g (3 mol with respect to 1 mol of the silane coupling agent) of 30% by mass hydrogen peroxide water was added thereto, and the mixture was boiled again. Thereafter, pure water replacement was performed for 2 hours, followed by cooling to room temperature (25° C.) to obtain sulfonic acid-modified colloidal silica (surface-modified silica 1).

### Production Example 2

Sulfonic acid-modified colloidal silica (surface-modified silica 2) was obtained by the same procedure as in Production Example 1, except that the addition amount of 3-mercaptopropyl trimethoxysilane (MPS) as the silane coupling agent was changed to 0.12 (silane coupling agent concentration with respect to the total mass of silica solid content: 0.06% by mass) in the item of (Surface modification step) in Production Example 1.

### Example 1

### Preparation of Polishing Composition

The sulfonic acid-modified colloidal silica (surface-modified silica 1, average secondary particle diameter: 34 nm) as the abrasive grains was added to water as the dispersing medium so as to have a final concentration of 2% by mass. Tetra-n-octylphosphonium bromide (manufactured by Tokyo Chemical Industry Co., Ltd.) was further added so as to have a final concentration of 200 ppm by mass, and stirred and mixed (stirring temperature: 25° C., stirring time: 20 minutes). The pH of the polishing composition was adjusted to 2.5 using nitric acid to complete the polishing composition.

### Example 2

A polishing composition was prepared in the same manner as in Example 1, except that tetra-n-butylphosphonium hydroxide (manufactured by Tokyo Chemical Industry Co., Ltd.) was used instead of tetra-n-octylphosphonium bromide.

### Example 3

A polishing composition was prepared in the same manner as in Example 1, except that tetraethylphosphonium bromide (manufactured by Tokyo Chemical Industry Co., Ltd.) was used instead of tetra-n-octylphosphonium bromide.

### Comparative Example 1

A polishing composition was prepared in the same manner as in Example 1, except that the quaternary phosphonium salt was not used.

### Comparative Example 2

A polishing composition was prepared in the same manner as in Example 1, except that 1-hydroxyethane-1,1-diphosphonic acid (HEDP, etidronic acid, Italmatch Chemicals S.p.A) was used instead of tetra-n-octylphosphonium bromide.

### Comparative Example 3

A polishing composition was prepared in the same manner as in Example 2, except that the abrasive grains were not used.

### Comparative Example 4

A polishing composition was prepared in the same manner as in Example 2, except that the sulfonic acid-modified colloidal silica (surface-modified silica 2, average secondary particle diameter: 34 nm) obtained in Production Example 2 was used as abrasive grains.

### Evaluation

As an object to be polished (substrate), a 300 mm wafer (SiOC film, manufactured by Advanced Materials Technology, Inc., product name: BD2x 5kA Blanket) and a 300 mm wafer (Si₃N₄ (silicon nitride film), manufactured by Advanced Materials Technology, Inc., product name: LP-SiN 3.5 KA Blanket) are cut into chips of 60 mm×60 mm to obtain coupons, and the coupons were used as test pieces.

Each of the prepared substrates was polished using the polishing composition obtained above under the following polishing conditions, and the polishing removal rate was measured.

### Polishing Conditions

Polishing machine: EJ-380IN-CH (manufactured by Engis Japan Corporation)

Polishing pad: Hard polyurethane pad (IC1010 manufactured by Nitta DuPont Co., Ltd.)

Polishing pressure: 2.0 psi (1 psi=6894.76 Pa)

Number of revolutions of platen (table): 60 rpm

Number of revolutions of head (carrier): 60 rpm

Flow rate of polishing composition: 100 ml/min

Polishing time: 30 seconds

### Polishing Removal Rate

The film thickness was determined by a light interference type film thickness measurement apparatus (Model No.: LAMBDA ACE VM-2030 manufactured by SCREEN Semiconductor Solutions Co., Ltd.), and the polishing removal rate was evaluated by dividing the difference in film thickness before and after polishing by the polishing time (see the following formula). Both the polishing removal rates of the SiOC film and the Si₃N₄ film are preferably 300 Å/min or more.

### Mathematical Formula 1

Polishing removal rate [Å/min]=(Film thickness [Å] before polishing−Film thickness [Å] after polishing)/Polishing time [min]

### Selection Ratio

The selection ratio was determined by dividing the polishing removal rate of the SiOC film obtained above by the polishing removal rate of the Si₃N₄ film (silicon nitride film). The selection ratio is preferably 1.0 or more and 2.0 or less.

The configurations and evaluation results of the polishing compositions of Examples and Comparative Examples are shown in Table 1 below. “−” in Table 1 indicates that the relevant agent is not used.

TABLE 1

| | Abrasive grains | | | | | | | | | | | |
|---|---|---|---|---|---|---|---|---|---|---|---|---|
| | | | Coupling agent | | | | | | | | | |
| | | | concentration | | | | | | | Evaluation | | |
| | | Average | with respect to | | Quaternary phosphonium salt | | | | | | | Selec- |
| | Concen- | secondary | total mass of | | | Concen- | Polishing composition | | | Polishing | | tion |
| | tration | particle | silica solid | Zeta | | tration | pH | | EC | removal rate | | ratio |
| | (% by | diameter | content (unit: | potential | | (ppm by | adjusting | | (mS/ | (Å/min) | | SiOC/ |
| | mass) | (nm) | % by mass) | (mV) | Type | mass) | agent | pH | cm) | SiOC | Si₃N₄ | Si₃N₄ |
| Example 1 | 2 | 34 | 0.6 | −19 | Tetra-n-octyl | 200 | Nitric acid | 2.5 | 2 | 656 | 351 | 1.9 |
| | | | | | phosphonium bromide | | | | | | | |
| Example 2 | 2 | 34 | 0.6 | −23 | Tetra-n-butyl | 200 | Nitric acid | 2.5 | 2 | 487 | 366 | 1.3 |
| | | | | | phosphonium hydroxide | | | | | | | |
| Example 3 | 2 | 34 | 0.6 | −35 | Tetraethyl | 200 | Nitric acid | 2.5 | 2 | 379 | 398 | 1.0 |
| | | | | | phosphonium bromide | | | | | | | |
| Comparative | 2 | 34 | 0.6 | −45 | — | — | Nitric acid | 2.5 | 2 | 210 | 418 | 0.5 |
| Example 1 | | | | | | | | | | | | |
| Comparative | 2 | 34 | 0.6 | −45 | HEDP | 200 | Nitric acid | 2.5 | 2 | 228 | 367 | 0.6 |
| Example 2 | | | | | | | | | | | | |
| Comparative | — | — | — | — | Tetra-n-butyl | 200 | Nitric acid | 2.5 | 2 | 1 | 1 | 1.0 |
| Example 3 | | | | | phosphonium hydroxide | | | | | | | |
| Comparative | 2 | 34 | 0.06 | −8 | Tetra-n-butyl | 200 | Nitric acid | 2.5 | 2 | 287 | 198 | 1.4 |
| Example 4 | | | | | phosphonium hydroxide | | | | | | | |

As is apparent from Table 1 above, it was found that when the polishing compositions of Examples were used, both the polishing removal rates of SiOC as the Low-k material and silicon nitride were 300 Å/min or more, and a high polishing removal rate was obtained. The ratio (selection ratio) of the polishing removal rate of SiOC to the polishing removal rate of silicon nitride was 1.0 or more and 2.0 or less, and it was found that an appropriate selection ratio was obtained. On the other hand, when the polishing compositions of Comparative Examples were used, the polishing removal rate of SiOC was low, and particularly, in the case of Comparative Examples 1 and 2, the selection ratio was decreased.

Table 1 above shows results obtained by separately polishing an object to be polished having a Low-k material (SiOC) and an object to be polished having silicon nitride. However, even when the object to be polished having both the Low-k material and silicon nitride is polished, it is estimated that the same results of the polishing removal rate and the selection ratio as those in Table 1 above can be obtained.

The present application is based on Japanese Patent Application No. 2023-039984 filed on Mar. 14, 2023, the disclosure content of which is incorporated herein by reference in its entirety.

What is claimed is:

1. A polishing composition comprising:
abrasive grains; and
a quaternary phosphonium salt,
wherein a pH is less than 7.0, and
a zeta potential of the abrasive grains in the polishing composition is −10 mV or less.

2. The polishing composition according to claim 1, wherein the quaternary phosphonium salt has at least one of a substituted or unsubstituted aryl group bonded to a phosphorus atom and a substituted or unsubstituted alkyl group bonded to a phosphorus atom.

3. The polishing composition according to claim 1, wherein the quaternary phosphonium salt has a substituted or unsubstituted alkyl group bonded to a phosphorus atom.

4. The polishing composition according to claim 1, wherein the quaternary phosphonium salt has a tetraalkylphosphonium cation, and a maximum number of carbon atoms of an alkyl group that the tetraalkylphosphonium cation has is 2 or more and 10 or less.

5. The polishing composition according to claim 4, wherein the quaternary phosphonium salt is at least one of tetra-n-butylphosphonium hydroxide and tetraethylphosphonium bromide.

6. The polishing composition according to claim 1, wherein the abrasive grains are anion-modified colloidal silica.

7. The polishing composition according to claim 1, further comprising a pH adjusting agent.

8. The polishing composition according to claim 1, further comprising a dispersing medium.

9. The polishing composition according to claim 1, wherein a concentration of an oxidizing agent in the polishing composition is less than 100 ppm by mass.

10. The polishing composition according to claim 1, wherein the zeta potential of the abrasive grains in the polishing composition is −40 mV or more and −15 mV or less.

11. The polishing composition according to claim 1, which is used for polishing an object to be polished containing a Low-k material and silicon nitride.

12. The polishing composition according to claim 11, wherein the Low-k material is SiOC.

13. The polishing composition according to claim 11, wherein a ratio of a polishing removal rate of the Low-k material to a polishing removal rate of the silicon nitride (Low-k material/silicon nitride) is 1.0 or more and 2.0 or less.

14. A polishing method comprising polishing an object to be polished containing a Low-k material and silicon nitride by using the polishing composition according to claim 1.

15. A method for producing a semiconductor substrate, comprising polishing a semiconductor substrate containing a Low-k material and silicon nitride by the polishing method according to claim 14.
